(19) United States
(12) Patent Application Publication
(10) Pub. No.: US 2026/0140177 A1
(43) Pub. Date: May 21, 2026

(54) SCAN CHAIN SEGMENTATION FOR AN INTEGRATED CIRCUIT

(71) Applicant: QUALCOMM Incorporated, San Diego, CA (US)

(72) Inventors: Rajesh Kumar Tiwari, Bangalore (IN); Yogesh Yadav, Surat (IN); Srinivas Patil, Austin, TX (US); Mohammed Zuber P Malek, Bengaluru (IN)

(21) Appl. No.: 18/955,599

(22) Filed: Nov. 21, 2024

(51) Int. Cl. G01R 31/3185

(52) U.S. Cl. CPC G01R 31/318536

(57) ABSTRACT

An apparatus includes a test controller and a scan chain coupled to the test controller. The scan chain includes a first segment and a second segment. The apparatus further includes circuitry coupled to the test controller and the scan chain. The circuitry is configured to provide, to the second segment, an output of the first segment in connection with a first test. The circuitry is further configured to provide, to the second segment, a test pattern in connection with a second test.

### TECHNICAL FIELD

Aspects of the present disclosure relate generally to integrated circuits, and more particularly, to testing of integrated circuits using scan chains.

### DESCRIPTION OF THE RELATED TECHNOLOGY

Electronic devices increasingly perform a variety of functions for users. For example, in addition to supporting voice calls, a mobile device (such as a smart phone) may support a variety of other operations and may include a variety of electronic components to support these operations. As another example, a vehicle may support wireless communications, navigation, and other driver assistance features such as adaptive cruise control, lane change assistance, collision avoidance, night vision, parking assistance, blind spot detection, lane keeping assistance, automated braking, partially autonomous driving, and fully autonomous driving.

To enable these and other features, devices may include one or more integrated circuits. One example of an integrated circuit is a system-on-chip (SoC). SoCs and other integrated circuits are typically subject to a variety of tests during design, production, and end use phases. Such testing may involve relatively sophisticated circuitry and testing processes, which may increase cost of the integrated circuits as well as the devices that include such integrated circuits.

### SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

In some aspects, an apparatus includes a test controller and a scan chain coupled to the test controller. The scan chain includes a first segment and a second segment. The apparatus further includes circuitry coupled to the test controller and the scan chain. The circuitry is configured to provide, to the second segment, an output of the first segment in connection with a first test. The circuitry is further configured to provide, to the second segment, a test pattern in connection with a second test.

In some additional aspects, a method includes initiating a test associated with a scan chain of an integrated circuit. The scan chain includes a first segment and a second segment. The method further includes selecting, during the test, as an input to the second segment, one of an output of the first segment or a test pattern that is input to the first segment. The method further includes receiving a test result associated with the scan chain. The test result is based on the selected input to the second segment.

In some further aspects, a non-transitory computer-readable medium stores instructions executable by one or more processors to perform one or more operations. The one or more operations include initiating a test associated with a scan chain of an integrated circuit. The scan chain includes a first segment and a second segment. The operations further include selecting, during the test, as an input to the second segment, one of an output of the first segment or a test pattern that is input to the first segment. The operations further include receiving a test result associated with the scan chain. The test result is based on the selected input to the second segment.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. It is intended that innovations described herein may be practiced in a wide variety of devices, chip-level components, systems, distributed arrangements, end-user devices, etc. of varying sizes, shapes, and constitution.

To the accomplishment of the foregoing and related ends, the one or more aspects include the features hereinafter described and pointed out in the claims. The following description and the drawings set forth in detail certain illustrative features of the one or more aspects. These features are indicative, however, of but a few of the various ways in which the principles of various aspects may be employed.

### BRIEF DESCRIPTION OF THE DRAWINGS

FIG. 1 is a block diagram illustrating an example of a system-on-chip (SoC) that supports scan chain segmentation.

FIG. 2 is a block diagram illustrating examples of features that support scan chain segmentation.

FIG. 3 is a block diagram illustrating an example of test circuitry that supports scan chain segmentation.

FIG. 4 is a block diagram illustrating another example of test circuitry that supports scan chain segmentation.

FIG. 5 is a block diagram illustrating another example of test circuitry that supports scan chain segmentation.

FIG. 6 is a flow chart illustrating an example of a method that supports scan chain segmentation.

Like reference numbers and designations in the various drawings indicate like elements.

### DETAILED DESCRIPTION

The detailed description set forth below in connection with the drawings describes various configurations and does not represent the only configurations in which the concepts described herein may be practiced. The detailed description includes specific details for the purpose of providing a thorough understanding of various concepts. However, these concepts may be practiced without these specific details. In some instances, well known structures and components are shown in block diagram form in order to avoid obscuring such concepts.

Various aspects relate generally to reconfiguration of a scan chain from a first length for at least a first test to a second length for at least a second test, where the second length is different than the first length. In some examples, a multiplexer (MUX) may include a first input coupled to an input of a first segment of the scan chain and may further include a second input coupled to an output of the first segment. An output of the MUX may be coupled to an input of a second segment of the scan chain. During some tests, the MUX may be used to reconfigure (e.g., shorten) a length of the scan chain (e.g., by selecting the input of the first segment as the output of the MUX). To further illustrate, during a self-test, the MUX may be used to reconfigure (e.g., shorten) the length of the scan chain. During one or more other tests (such as a production test), the output of the first segment may be selected as the output of the MUX (e.g., to facilitate testing of the entire scan chain).

Particular aspects of the subject matter described in this disclosure can be implemented to realize one or more of the following potential advantages. In some examples, by reconfiguring the length of one or more scan chains, a duration of one or more tests of an integrated circuit (e.g., a self-test of the integrated circuit) may be reduced. For example, because the duration of such a test may be proportional to the length of a scan chain, reducing the length of the scan chain may decrease the duration of the test, which may enhance user experience (e.g., by reducing boot-up time). Further, such reconfiguration of the length of the scan chain may be disabled during one or more other tests, such as a production test that may involve a greater test resolution or a lower test compression as compared to the self-test. As a result, the duration and power consumption associated with some tests (such as the self-test) may be reduced without decreasing reliability or accuracy of one or more other tests, such as the production test.

Several aspects are presented with reference to various apparatus and methods. These apparatus and methods are described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. When multiple processors are implemented, the multiple processors may perform the functions individually or in combination. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software, whether referred to as software, firmware, middleware, microcode, hardware description language, or otherwise, shall be construed broadly to mean instructions, instruction sets, code, code segments, program code, programs, subprograms, software components, applications, software applications, software packages, routines, subroutines, objects, executables, threads of execution, procedures, functions, or any combination thereof. One or more processors in the processing system may execute software to cause a device that includes the one or more processors to perform the various functionality described throughout this disclosure.

Accordingly, in one or more example aspects, implementations, and/or use cases, the functions described may be implemented in hardware, software, or any combination thereof. If implemented in software, the functions may be stored on or encoded as one or more instructions or code on a computer-readable medium. Computer-readable media include computer storage media. Storage media may be any available media that can be accessed by a computer. By way of example, such computer-readable media can include a random-access memory (RAM), a read-only memory (ROM), an electrically erasable programmable ROM (EEPROM), optical disk storage, magnetic disk storage, other magnetic storage devices, combinations of the types of computer-readable media, or any other medium that can be used to store computer executable code in the form of instructions or data structures that can be accessed by a computer (e.g., transitory or non-transitory medium that may be accessed by computer).

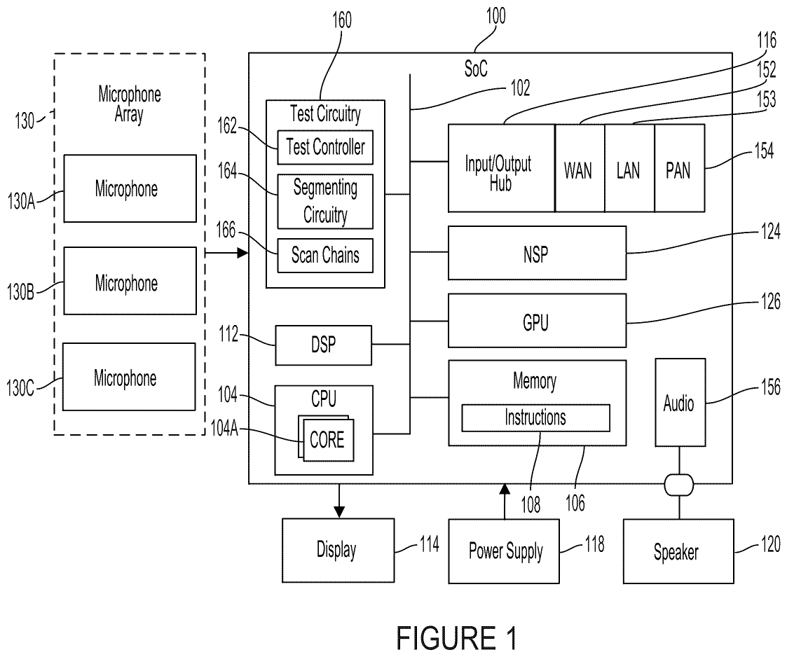

FIG. 1 is a block diagram illustrating an example of a system-on-chip (SoC) 100 that supports scan chain segmentation. The SoC 100 may include several components coupled together through a bus 102, which may be a network-on-a-chip (NoC) or a plurality of NOCs interconnecting various components. For example, although FIG. 1 illustrates several components coupled to the bus 102, the several components may be coupled to different busses with additional busses connecting the different busses to provide a path for communication between the components.

One example component in the SoC 100 is a digital signal processor (DSP) 112 for signal processing. The DSP 112 may process audio signals received from microphones 130A, 130B, and 130C of microphone array 130. The DSP 112 may include hardware customized for performing a limited set of operations on specific kinds of data. For example, a DSP may include transistors coupled together to perform operations on streaming data and use memory architectures and/or access techniques to fetch multiple data or instructions concurrently. Such configurations may allow the DSP 112 to operate on real-time data, such as video data, audio data, or modem data, in a power-efficient manner.

The SoC 100 also includes a central processing unit (CPU) 104 and a memory 106 storing instructions 108 (e.g., a memory storing processor-readable code or a non-transitory computer-readable medium storing instructions) that may be executed by a processor of the SoC 100. The CPU 104 may be a single central processing unit (CPU) or a CPU cluster comprising two or more cores such as core 104A. The CPU 104 may include hardware capable of performing generic operations on many kinds of data, such as hardware capable of executing instructions from the Advanced RISC Machines (ARM®) instruction set, such as ARMv8 and ARMv9. For example, a CPU 104 may include transistors coupled together to perform operations for supporting executing an operating system and user applications (e.g., a camera application, a multimedia application, a gaming application, a productivity application, a messaging application, a videocall application, an audio recording application, a video recording application). The CPU 104 may execute instructions 108 retrieved from the memory 106. In some embodiments, the CPU 104 executing an operating system may coordinate execution of instructions by various components within the SoC 100. For example, the CPU 104 may retrieve instructions 108 from memory 106 and execute the instructions on the DSP 112.

The SoC 100 may further include a neural signal processor (NSP) 124 for executing machine learning (ML) models relating to multimedia applications. The NSP 124 may include hardware configured to perform and accelerate convolution operations involved in executing machine learning algorithms. For example, the NSP 124 may improve performance when executing predictive models such as artificial neural networks (ANNs) (including multilayer feedforward neural networks (MLFFNN), the recurrent neural networks (RNN), and/or the radial basis functions (RBF)). The ANN executed by the NSP 124 may access predefined training weights stored in the memory 106 for performing operations on user data.

The SoC 100 may be coupled to a display 114 for interacting with a user. The SoC 100 may also include a graphics processing unit (GPU) 126 for rendering images on the display 114. In some embodiments, the CPU 104 may perform rendering to the display 114 without a GPU 126. In some embodiments, the GPU 126 may be configured to execute instructions for performing operations unrelated to rendering images, such as for processing large volumes of datasets in parallel.

Input/output components may be coupled to the SoC 100 through an input/output (I/O) hub 116. An example of a hub 116 is an interconnect to a peripheral component interconnect express (PCIe) bus. Example components coupled to hub 116 may be components used for interacting with a user, such as a touch screen interface and/or physical buttons. Some components coupled to hub 116 may also include network interfaces for communicating with other devices, including a wide area network (WAN) adaptor (e.g., WAN adaptor 152), a local area network (LAN) adaptor (e.g., LAN adaptor 153), and/or a personal area network (PAN) adaptor (e.g., PAN adaptor 154). A WAN adaptor 152 may be a 4G LTE or a 5G NR wireless network adaptor. A LAN adaptor 153 may be an IEEE 802.11 WiFi wireless network adapter. A PAN adaptor 154 may be a Bluetooth wireless network adaptor. Each of the WAN adaptor 152, LAN adaptor 153, and/or PAN adaptor 154 may be coupled to an antenna that may be shared by each of the adaptors 152, 153, and 154, or coupled to multiple antennas configured for primary and diversity reception and/or configured for receiving specific frequency bands. In some embodiments, the WAN adaptor 152, LAN adaptor 153, and/or PAN adaptor 154 may share circuitry, such as portions of a radio frequency front end (RFFE).

Audio circuitry 156 may be integrated in SoC 100 as dedicated circuitry for coupling the SoC 100 to a speaker 120 external to the SoC 100, which may be a transducer such as a speaker (either internal to or external to a device incorporating the SoC 100) or headphones. The audio circuitry 156 may include coder/decoder (CODEC) functionality for processing digital audio signals. The audio circuitry 156 may further include one or more amplifiers (e.g., a class-D amplifier) for driving a transducer coupled to the SoC 100 for outputting sounds generated during execution of applications by the SoC 100. Functionality related to audio signals described herein may be performed by a combination of the audio circuitry 156 and/or other processors of the SoC (e.g., CPU 104, DSP 112, GPU 126, NSP 124).

The SoC 100 may couple to external devices outside the package of the SoC 100. For example, the SoC 100 may be coupled to a power supply 118, such as a battery or an adaptor to couple the SoC 100 to an energy source. The signal processing described herein may be adapted to and achieve power efficiency to support operation of the SoC 100 from a limited-capacity power supply 118 such as a battery. For example, operations may be performed on a portion of the SoC 100 configured for performing the operation at a lowest power consumption. As another example, operations themselves are performed in a manner that reduces an amount of computations to perform the operation, such that the algorithm is optimized for extending the operational time of a device while powered by a limited-capacity power supply 118. In some embodiments, the operations described herein may be configured based on a type of power supply 118 providing energy to the SoC 100. For example, a first set of operations may be executed to perform a function when the power supply 118 is a wall adaptor. As another example, a second set of operations may be executed to perform a function when the power supply 118 is a battery.

The SoC 100 may also include or be coupled to additional features or components that are not shown in FIG. 1. Although components are shown integrated as a single SoC 100, which may include all components built on a single semiconductor die with a common semiconductor substrate, other arrangements of the illustrated blocks different number of dies, substrates, and/or packages may be arranged to accomplish the same functionality described in this disclosure. Further, although some examples herein are described with reference to the SoC 100, it should be appreciated that the features described herein are also applicable to other types of integrated circuits.

The memory 106 may include a non-transient or non-transitory computer readable medium storing computer-executable instructions as instructions 108 to perform all or a portion of one or more operations described in this disclosure. The instructions 108 may include a multimedia application (or other suitable application such as a messaging application) to be executed by the SoC 100 that records, processes, or outputs audio signals. The instructions 108 may also include other applications or programs executed by the SoC 100, such as an operating system and applications other than for multimedia processing.

In addition to instructions 108, the memory 106 may also store audio data. The SoC 100 may be coupled to an external memory and configured to access the memory for writing output audio files for later playback or long-term storage. For example, the SoC 100 may be coupled to a flash storage device comprising NAND memory for storing video files (e.g., MP4-container formatted files) including audio tracks and/or storing audio recordings (e.g., MPEG-1 Layer 3 files, also referred to as MP3 files). Portions of the video or audio files may be transferred to memory 106 for processing by the SoC 100, with the resulting signals after processing encoded as video or audio files in the memory 106 for transfer to the long-term storage.

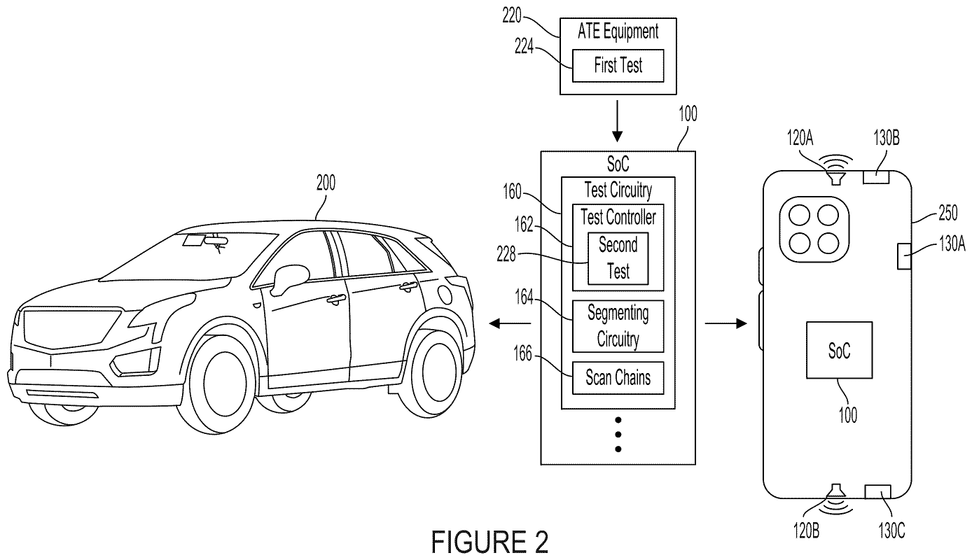

The SoC 100 may further include test circuitry 160. In some examples, the test circuitry 160 may include a test controller 162, segmenting circuitry 164, and scan chains 166. The scan chains 166 may be coupled to the test controller 162 and to the segmenting circuitry 164. At least some of the test circuitry 160 may perform or be may used in connection with multiple tests. The segmenting circuitry 164 may be configured to segment at least one of the scan chains 166 into segments for at least some tests, as described further below. In some examples, the test circuitry 160 may perform or may be involved in multiple tests during multiple different phases of design, production, and operation of the SoC 100, as described further with reference to FIG. 2.

FIG. 2 is a block diagram illustrating examples of features that support scan chain segmentation. In the example of FIG. 2, the SoC 100 may be subject to a first test 224 and a second test 228. The first test 224 and the second test 228 may both use (or “share”) at least some components of the test circuitry 160, such as one or more of the test controller 162, the segmenting circuitry 164, and the scan chains 166.

The first test 224 and the second test 228 may be performed at different phases of design, production, and operation of the SoC 100. To illustrate, in some examples, the first test 224 may be performed during one of a design phase, a production phase, a debugging phase, a production phase, or a repair phase, and the second test 228 may be performed during another one of the design phase, the production phase, the debugging phase, the production phase, or the repair phase. To further illustrate, in some examples, the first test 224 may include or correspond to one or more of a structural test, an automatic test pattern generation (ATPG) test, an automated test equipment (ATE) production screening test, a Joint Test Action Group (JTAG) test, or a boundary scan test, and the second test 228 may include or correspond to one or more of a functional test, a built-in self-test (BIST), a periodic BIST, a logic built-in self-test (LBIST), or a memory built-in self-test (MBIST). In some examples, the first test 224 may be performed using automated test equipment (ATE) 220. In some examples, the second test 228 may be performed during post-production operation of the SoC 100, such as after the SoC 100 is deployed in a vehicle 200 or a mobile device 250, as illustrative examples.

In some scenarios, the first test 224 may be associated with a first test compression, and the second test 228 may be associated with a second test compression that is greater than the first compression. A test compression may refer to or may be associated with an amount of data reduction applied to one or more of an input test pattern or an output test result. Further, a higher test compression may involve a lower test resolution, and vice versa. A greater test resolution (and a lower test compression) may be associated with more accurate or reliable test results but may also be associated with a greater test duration. In some examples, the first test 224 may be associated with one or more test operations not included in the second test 228, such as certain diagnostics and failure analysis tests. As a result, the first test 224 may be associated with a lower test compression (and a greater test resolution) as compared to the second test 228.

In some examples, the segmenting circuitry 164 may be configured to enable a first length of the at least one scan chain 166 during the first test 224. The segmenting circuitry 164 may be further configured to reconfigure the at least one scan chain 166 to a second length that is less than the first length in connection with the second test 228 (e.g., to reduce a duration of the second test 228 as compared to the first test 224).

In some examples, one or more of the vehicle 200 or the mobile device 250 may include or may be referred to as a user equipment (UE). Examples of UEs may include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs may be referred to as IoT devices (e.g., parking meter, gas pump, toaster, vehicles, heart monitor, etc.). A UE may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. In some scenarios, the term UE may also apply to one or more companion devices such as in a device constellation arrangement. One or more of these devices may collectively access the network and/or individually access the network.

In some examples, the vehicle 200 may operate using assisted driving and/or autonomous driving capabilities. Assisted driving, which may also be called advanced driver assistance systems (ADAS), may refer to a set of technologies designed to enhance vehicle safety and improve the driving experience by providing assistance and automation to the driver. These technologies may use various sensor(s), such as camera(s), radar(s), light detection and ranging (lidar(s) or lidar sensor(s)), etc., and other components to monitor a vehicle's surroundings and assist the driver of the vehicle 200 with certain driving tasks. For example, some features of assisted driving systems may include: (1) adaptive cruise control (ACC) (e.g., a system that automatically adjusts a vehicle's speed to maintain a safe following distance from the vehicle ahead), (2) lane-keeping assist (LKA) (e.g., a system that uses cameras to detect lane markings and helps keep the vehicle 200 centered within the lane, and provides steering inputs to prevent unintentional lane departure), (3), autonomous emergency braking (AEB) (e.g., a system that detects potential collisions with obstacles or pedestrians and automatically apply the brakes to avoid or mitigate the impact), (4) blind spot monitoring (BSM) (e.g., a system that uses sensors to detect vehicles in a driver's blind spots and provides visual or audible alerts to avoid potential collisions during lane changes), (5) parking assistance (e.g., a system that assists drivers in parking their vehicles by using camera(s) and sensor(s) to help with parallel parking or maneuvering into tight spaces), and/or traffic sign recognition (e.g., camera(s) and image processing are used to recognize and display traffic signs such as speed limits, stop signs, and other road regulations on the dashboard of the vehicle 200).

Autonomous driving, which may also be called as self-driving or driverless technology, may refer to the ability of the vehicle 200 to navigate and operate itself without specifying human intervention (e.g., travelling from one place to another place without a human controlling the vehicle). The goal of the autonomous driving is to create vehicles that are capable of perceiving their surroundings, making decisions, and controlling their movements, all without the direct involvement of a human driver. To achieve or improve the autonomous driving, the vehicle 200 may be specified to use a map (or map data) with detailed information, such as a high-definition (HD) map. An HD map may refer to a highly detailed and accurate digital map designed for use in autonomous driving and ADAS. In one example, HD maps may typically include one or more of: (1) geometric information (e.g., precise road geometry, including lane boundaries, curvature, slopes, and detailed 3D models of the surrounding environment), (2) lane-level information (e.g., information about individual lanes on the road, such as lane width, lane type (e.g., driving, turning, or parking lanes), and lane connectivity), (3) road attributes (e.g., data on road features like traffic signs, signals, traffic lights, speed limits, and road markings), (4) topology (e.g., information about the relationships between different roads, intersections, and connectivity patterns), (5) static objects (e.g., locations and details of fixed objects along the road, such as buildings, traffic barriers, and poles), (6) dynamic objects (e.g., real-time or frequently updated data about moving objects, like other vehicles, pedestrians, and cyclists), and/or (7) localization and positioning: precise reference points and landmarks that help in accurate vehicle localization on the map, etc.

Note while some assisted/autonomous driving systems may demand the use of HD map data, there are also assisted/autonomous driving systems and information systems that may be configured not to use HD map data (e.g., due to costs). For example, the Society of Automotive Engineers (SAE) has defined six levels of driving automation, from Level 0 (no automation) to Level 5 (full automation). For Level 0 (no automation), the human driver may be responsible for all aspects of driving, and the system may provide warnings or momentary assistance but does not take control of the vehicle 200. Example features for SAE Level 0 may include automatic emergency braking, blind spot warnings, and lane departure warnings, etc. As such, SAE Level 0 may not specify using HD map data. For Level 1 (driver assistance), the vehicle 200 may assist with either steering or acceleration/deceleration (but may not perform both simultaneously). The human driver is still responsible for most driving tasks and may need to be ready to take over at any time. Example features for SAE Level 1 may include adaptive cruise control or lane-keeping assistance (e.g., lane centering), etc. For Level 2 (partial automation), the vehicle 200 may control both steering and acceleration/deceleration under certain conditions, but the human driver is requested to remain engaged and monitor the driving environment at all times. Example features for SAE Level 2 may include ADAS, adaptive cruise control and lane-keeping assistance at the same time, etc. For Level 3 (conditional automation), the vehicle 200 may perform all driving tasks under specific conditions, and the human driver may not be specified to monitor the environment but may need to be ready to take over when requested by the system. Example features for SAE Level 3 may include traffic jam chauffeur, where the vehicle 200 is capable of handling driving in traffic jams without driver intervention. For Level 4 (high automation), the vehicle 200 is capable of handling all driving tasks within certain conditions or environments (geofenced areas). The system may operate without human intervention but may specify a human driver outside its operational domain. Example features for SAE Level 4 may include local driverless taxi and pedals/steering, etc. For Level 5 (full automation), the vehicle 200 is capable of performing all driving tasks under all conditions, and does not specify the human driver at any time. Example features for SAE Level 5 may include fully autonomous vehicles with no steering wheel or pedals. In summary, SAE Level 0 may be defined as features to provide warnings and assistance. ADAS is usually SAE Level 1 and 2, while AD is considered SAE level 3 to 5. Aspects presented herein (described below) may apply to all levels of SAE, including SAE Level 0 (e.g., for speed warning). For purposes of the present disclosure, a system or information system that is used in associated with SAE Level 0 to Level 5 may collectively be referred to as a “vehicle system,” which may encompass the assisted driving and the autonomous driving.

To enable assisted driving and/or autonomous driving, the vehicle 200 may be configured to use various machine learning (ML) and/or neural network (NN) frameworks. An ML/NN framework may refer to a set of tools, libraries, and/or software components that are configured to provide a structured way to design, build, and deploy ML/NN models and applications. These frameworks may be able to simplify the process of developing ML/NN algorithms and applications by providing a foundation of pre-built functions, algorithms, and utilities. They may typically include features for data preprocessing, model training, evaluation, and/or deployment, etc. ML/NN frameworks may come in various programming languages, and they may be configured to cater to different types of machine learning tasks, including supervised learning, unsupervised learning, and/or reinforcement learning, etc. An ML/NN model may refer to a mathematical representation of a real-world process or problem, created using ML/NN algorithms and techniques. These ML/NN models may be configured to make predictions, classify data, and/or solve specific tasks based on patterns and relationships learned from input data. A deep learning framework may refer to a specialized software library or toolset that provides specified components and abstractions for building, training, and deploying deep neural networks. Deep learning frameworks may be designed to facilitate the development of complex neural network models, especially deep neural networks with multiple layers. These frameworks may offer a wide range of pre-implemented layers, optimizers, loss functions, and other components, making it easier for researchers and developers to work with deep learning models.

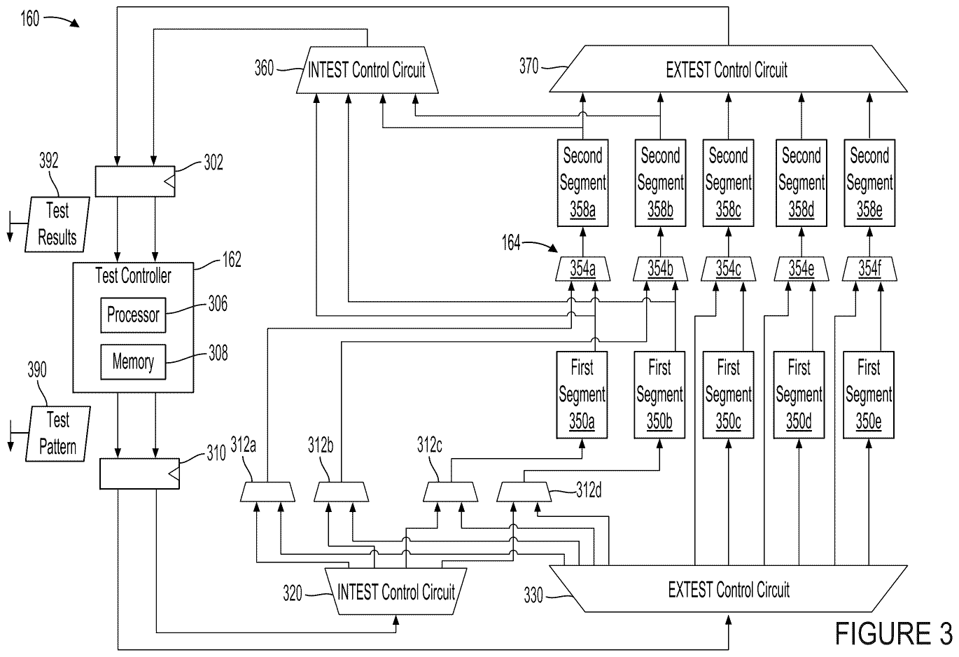

FIG. 3 is a block diagram illustrating an example of test circuitry 160 that supports scan chain segmentation. The test circuitry 160 may include the test controller 162. The test controller 162 may include one or more processors (such as a processor 306) and one or more memories (such as a memory 308) coupled to the one or more processors. The test circuitry 160 may further include latches 302, 310 coupled to the test controller 162. The test circuitry 160 may further include an internal test (INTEST) control circuit 320 and an external (EXTEST) control circuit 330 that may be coupled to the latch 310. The test circuitry 160 may also include an INTEST control circuit 360 and an EXTEST control circuit 370 that may be coupled to the latch 302.

The test circuitry 160 may further include the segmenting circuitry 164. In the example of FIG. 3, the segmenting circuitry 164 may include multiplexers (MUXes) 354a-f. In addition, the test circuitry 160 may include scan chains having segments coupled to the segmenting circuitry 164. For example, first segments 350a-e may be coupled to inputs of the MUXes 354a-f, and second segments 358a-e may be coupled to outputs of the MUXes 354a-f. The first segments 350a-e and the second segments 358a-e may be included in the scan chains 166. For example, the first segment 350a and the second segment 358a may form a first scan chain of the scan chains 166, and the first segment 350b and the second segment 358b may form a second scan chain of the scan chains 166.

The test circuitry 160 may also include MUXes 312a-d. Each of the MUXes 312a-d may include an input coupled to an output of the INTEST control circuit 320. Each of the MUXes 312a-d may also include another input coupled to an output of the EXTEST control circuit 330. In the example of FIG. 3, outputs of the MUXes 312a-b may be coupled to inputs of the MUXes 354a-b, respectively, and outputs of the MUXes 312c-d may be coupled to inputs of the first segments 350a-b, respectively.

In some examples, control circuits (such as the control circuits 320, 330, 360, and 370) may be referred to as, or may be associated with, a codec. The segments 350a-b and 358a-b may form or may be referred to as wrapper chains (e.g., where the segments 350a and 358a form one wrapper chain, and where the segments 350b and 358b form another wrapper chain). The segments 350c-e and 358c-e may form or may be referred to as core chains (e.g., where the segments 350c and 358c form one core chain, where the segments 350d and 358d form another core chain and where the segments 350e and 358e form another core chain).

Although the example of FIG. 3 may illustrate five scan chains, in other examples, a different quantity of scan chains may be used. Further, although the example of FIG. 3 may illustrate two segments of each such scan chain, in other examples, a different quantity of scan chains may be used (e.g., three segments per scan chain, four segments per scan chain, or another quantity of segments). Further, different segments within a scan chain may be of different lengths. Alternatively, or in addition, segments of different scan chains may be of different lengths.

During operation, the segmenting circuitry 164 may segment one or more of the scan chains 166 into segments of different lengths, as described further below. To illustrate, the segmenting circuitry 164 may be configured to enable a first length of the one or more scan chains 166 during the first test 224 of FIG. 2 and to enable a second length of the one or more scan chains 166 during the second test 228 of FIG. 2, where the second length is less than the first length.

To illustrate, the test controller 162 may provide test patterns to the INTEST control circuit 320 and the EXTEST control circuit 330, such as a test pattern 390. During the first test 224 of FIG. 2, the control circuits 320, 330 and the MUXes 312a-d may provide the test pattern 390 to the first segments 350a-e. In this example, the first segments 350a-e may receive the test pattern 390 and may output test data to the MUXes 354 based on the test pattern 390. The MUXes 354 may select the test data and may output the test data to the second segments 358a-f. The second segments 358a-f may receive the test data and may output additional test data, such as test results 392. The control circuits 360, 370 may receive the test results 392 and may provide the test results 392 to the test controller 162. Accordingly, the first segments 350a-e may contribute to the test results 392 in connection with the first test 224 of FIG. 2.

During the second test 228 of FIG. 2, the MUXes 354a-f may receive the test pattern 390 from the MUXes 312a-b and the EXTEST control circuit 330 (instead of receiving test data from the first segments 350a-e). In such examples, the MUXes 354a-f may select the outputs of the MUXes 312a-b and the EXTEST control circuit 330 (instead of selecting the outputs of the first segments 350a-e). The MUXes 354a-f may output the test pattern 390 to the second segments 358a-e. Accordingly, the MUXes 354a-f may selectively provide one of the test data from the first segments 350a-e (e.g., during the first test 224 of FIG. 2) or the test pattern 390 from the MUXes 312a-b and the EXTEST control circuit 330 (e.g., during the second test 228 of FIG. 2) to the second segments 358a-e.

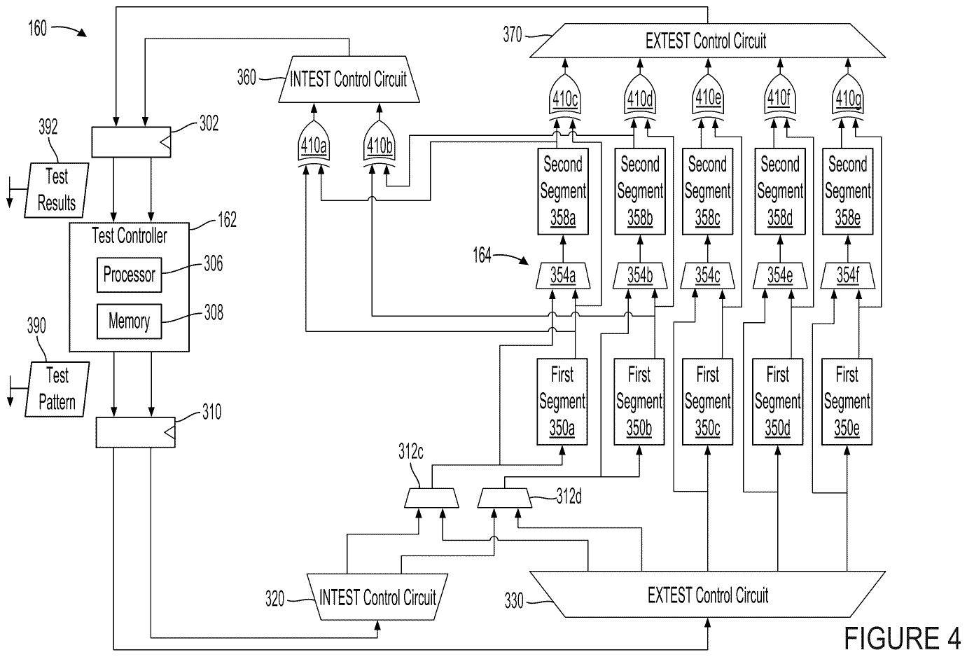

FIG. 4 is a block diagram illustrating another example of test circuitry 160 that supports scan chain segmentation. In the example of FIG. 4, an output of the MUX 312c may be coupled to inputs of the first segment 350a and the MUX 354a, and an output of the MUX 312d may be coupled to inputs of the first segment 350a and the MUX 354a.

In the example of FIG. 4, the test circuitry 160 may further include exclusive-OR (XOR) gates 410a-g. Outputs of the XOR gates 410a-b may be coupled to an input of the INTEST control circuit 360, and outputs of the XOR gates 410c-g may be coupled to an input of the EXTEST control circuit 370. The XOR gate 410a may include a first input coupled to an output of the first segment 350a and a second input coupled to an output of the second segment 358a. The XOR gate 410b may include a first input coupled to an output of the first segment 350b and a second input coupled to an output of the second segment 358b. The XOR gates 410c-g may each include a first input coupled to an output of a respective one of the first segments 350a-e and may also each include a second input coupled to an output of a respective one of the second segments 358a-e.

During operation, the XOR gates 410a-g may receive first results from the first segments 350a-f and may receive second results from the second segments 358a-f. The XOR gates 410a-g may perform XOR operations based on the first results and the second results to generate test results associated with the scan chains 166, such as the test results 392. As an example, the XOR gate 410a may perform an XOR operation based on a first result generated by the first segment 350a and further based on a second result generated by the second segment 358a to generate a test result associated with a scan chain that includes the first segment 350a and the second segment 358a. In some examples, the test result may be included in the test results 392.

By using the XOR gates 410a-g, an amount of test results may be reduced (e.g., by “compressing” results from multiple segments of a scan chain via an XOR operation). As a result, in the example of FIG. 4, a size (or “length”) of the control circuits 320, 330 360, and 370 may be reduced as compared to the example of FIG. 3, which may reduce cost or complexity of the test circuitry 160 in some implementations.

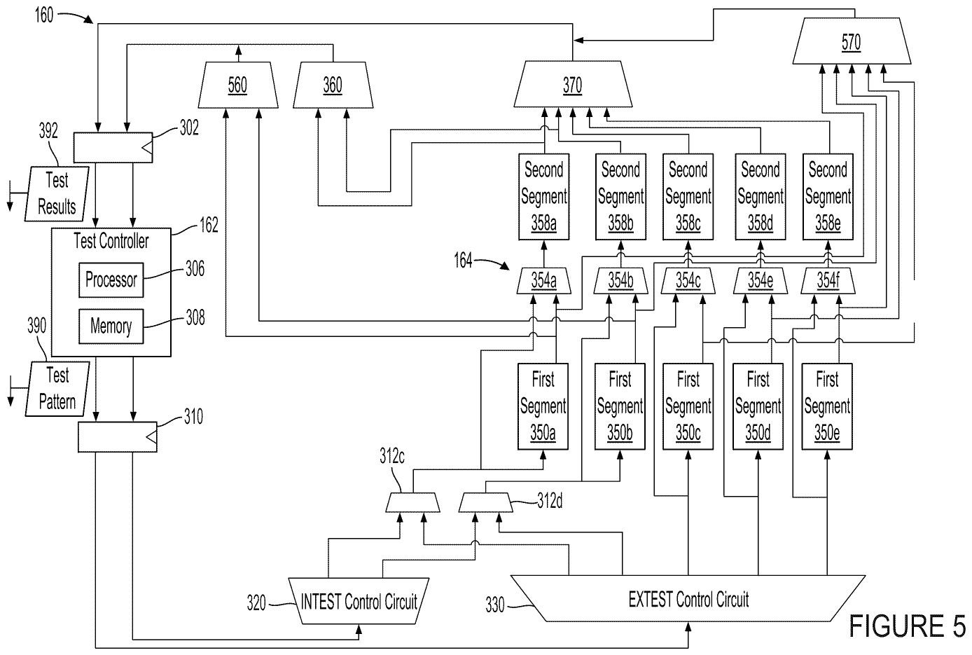

FIG. 5 is a block diagram illustrating another example of test circuitry 160 that supports scan chain segmentation. In the example of FIG. 5, the test circuitry 160 may further include an INTEST control circuit 560 and an EXTEST control circuit 570.

In some examples, one or more of the INTEST control circuit 560 or the EXTEST control circuit 570 may be included in, or may correspond to, a control circuit. The control circuit may include a first input coupled to an output of the first segment 350a and a second input coupled to at least one other output of at least one other first segment in another scan chain (e.g., an output of the first segment 350b in another scan chain that includes the first segment 350b and the second segment 358b). The control circuit may further include an output configured to output test data associated with the first segment (e.g., the first segment 350a) and the at least one other first segment (e.g., the first segment 350b). In some examples, the test data may be included in the test results 392. In some examples, the control circuit may include one or more of an INTEST multiple-input signature register (MISR) included in the INTEST control circuit 560 or an EXTEST MISR included in the EXTEST control circuit 570.

To further illustrate, in some examples, a scan chain segment of length X may be created. A number of chains in an LBIST mode may equal a number of chains in an ATPG mode multiplied by N (e.g., where N=2, 3, 4, or another value). An LBIST codec may be created with a number of internal chains based on the value of N, such as 2X (for N=2) or 3X (for N=3). A number of LBIST chains may be less than ((MISR_length−1)*(MISR_length−2) )/2, where MISR_length may indicate a length of a control circuit, such as any of the control circuits 320, 330, 360, and 370. To illustrate, if MISR_length=128, then the maximum number of LBIST chains may be less than 127*126/2 =8001. Some such implementations may involve widening a codec by 2X (for N=2) or 3X (for N=3) and thus may involve a similar number of added connections.

In some examples, to reduce a number of such connections and codec width, test values may be compressed (e.g., as illustrated in the example of FIG. 4). For example, values may be broadcast to an input side, and values may be combined from multiple scan chains on the output side prior to providing the values to a MISR (such as one or more of the control circuits 360, 370). Additional routing for segmentation may be included in a scan chain.

In some further examples, instead of compressing test values in such a manner, scan chain outputs may be fed to separate MISRs (e.g., as illustrated in the example of FIG. 5). Such a technique may involve an increased number of connections on an output side of a codec (e.g., where the example illustrated in FIG. 5 may involve twice the number of connections on an output side of the code as compared to the examples of FIGS. 3 and 4).

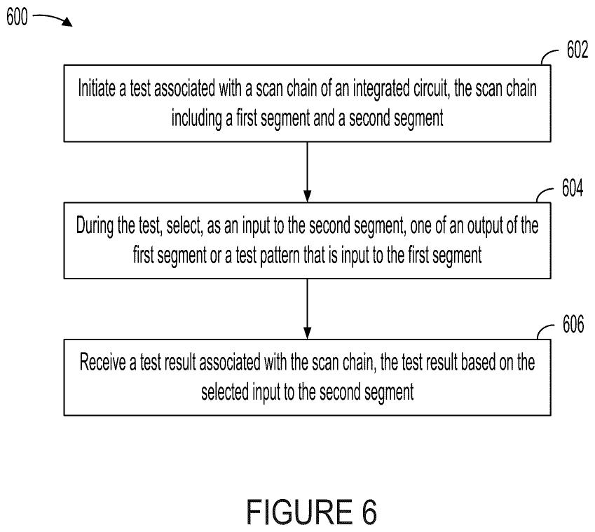

FIG. 6 is a flow chart illustrating an example of a method 600 that supports scan chain segmentation. In some examples, one or more operations of the method 600 may be initiated, performed, or controlled by one or more processors, such as by a processor of the ATE equipment 220, by the processor 306 of the test controller 162, by one or more other processors, or a combination thereof.

The method 600 includes initiating a test associated with a scan chain of an integrated circuit, at 602. The scan chain includes a first segment and a second segment. To illustrate, the integrated circuit may correspond to the SoC 100, and the test may correspond to the first test 224 or the second test 228. The scan chain may correspond to one of the scan chains 166, the first segment may correspond to one of the first segments 350a-e, and the second segment may correspond to one of the second segments 358a-e.

The method 600 further includes, during the test, selecting, as an input to the second segment, one of an output of the first segment or a test pattern that is input to the first segment, at 604. To illustrate, in one example, an output of the first segment 350a may be selected by the MUX 354a (e.g., based on a first value of a control signal provided to the MUX 354a) during the first test 224. In this example, the output of the first segment 350a may be provided as the selected input to the second segment 358a. In another example, the test pattern 390 (or a portion of the test pattern 390) may be selected by the MUX 354a (e.g., based on a second value of the control signal provided to the MUX 354a) during the second test 228. In this example, the test pattern 390 (or a portion of the test pattern 390) may be provided as the selected input to the second segment 358a.

The method 600 further includes receiving a test result associated with the scan chain, at 606. The test result is based on the selected input to the second segment. For example, the test result may be included in or may correspond to the test results 392, and the test results 392 may be based on the selected input to at least one of the second segments 358a-f.

In some examples, the test may correspond to a structural test of the integrated circuit, and the selected input to the second segment may correspond to the output of the first segment. In some other examples, the test may correspond to a functional test of the integrated circuit, and the selected input to the second segment may correspond to the test pattern.

In some examples, the scan chain may be associated with a first length in connection with the output of the first segment being the selected input to the second segment, and the scan chain may be associated with a second length in connection with the test pattern being the selected input to the second segment. The second length is less than the first length.

In some implementations, selecting the input to the second segment may include providing a control signal to a multiplexer (MUX) that is coupled to the first segment and to the second segment. As an illustrative example, the selecting the input to the second segment 358a may include providing a control signal to the MUX 354a, where a value of the control signal selects the input to the second segment 358a.

In some examples, the method 600 may further include performing an exclusive-OR (XOR) operation to generate the test result based on a first result from the first segment and further based on a second result from the second segment. For example, the XOR operation may be performed by one or more of the XOR gates 410a-g.

In some implementations, the method 600 may further include providing the output of the first segment to one of a first internal test (INTEST) multiple input signature register (MISR) (e.g., the INTEST control circuit 560) or to a first external test (EXTEST) MISR (e.g., the EXTEST control circuit 570). The method 600 may also include providing a second output of the second segment to one or more of a second INTEST MISR (e.g., the

INTEST control circuit 360) or a second EXTEST MISR (e.g., the EXTEST control circuit 370).

In some aspects, a non-transitory computer-readable medium may store instructions executable by one or more processors to perform one or more operations described herein, such as one or more operations of the method 600 of FIG. 6. The one or more processors may include or may correspond to a processor of the ATE equipment 220, the processor 306 of the test controller 162, one or more other processors, or a combination thereof. The non-transitory computer-readable medium may correspond to ta memory of the ATE equipment 220, memory 308 of the test controller 162, one or more other memories, or a combination thereof.

One or more features described herein may reduce a duration of one or more tests of an integrated circuit, such as the second test 228 of the SoC 100. For example, because the duration of such a test may be proportional to the length of a scan chain 166, reducing the length of a scan chain 166 may decrease the duration of a self-test, which may enhance user experience (e.g., by reducing boot-up time). Further, such reconfiguration of a scan chain 166 may be disabled during one or more other tests, such as a production test (e.g., the first test 224) that may involve a greater test resolution or a lower test compression as compared to the self-test. As a result, the duration and power consumption associated with some tests (such as the second test 228) may be reduced without decreasing reliability or accuracy of one or more other tests, such as the first test 224.

In a first aspect, an apparatus includes a test controller and a scan chain coupled to the test controller. The scan chain includes a first segment and a second segment. The apparatus further includes circuitry coupled to the test controller and the scan chain. The circuitry is configured to provide, to the second segment, an output of the first segment in connection with a first test. The circuitry is further configured to provide, to the second segment, a test pattern in connection with a second test.

In a second aspect, in combination with the first aspect, the first test corresponds to a structural test of an integrated circuit, and the second test corresponds to a functional test of the integrated circuit.

In a third aspect, in combination with one or more of the first aspect or the second aspect, the first test is associated with a first length of the scan chain, and the second test is associated with a second length of the scan chain, the second length less than the first length.

In a fourth aspect, in combination with one or more of the first aspect through the third aspect, the circuitry includes a plurality of multiplexers (MUXes).

In a fifth aspect, in combination with one or more of the first aspect through the fourth aspect, the apparatus further includes an exclusive-OR (XOR) gate coupled to an output of the second segment.

In a sixth aspect, in combination with one or more of the first aspect through the fifth aspect, the XOR gate includes a first input coupled to a first output of the first segment and configured to receive a first result from the first segment, a second input coupled to a second output of the second segment and configured to receive a second result from the second segment, and an output configured to perform an XOR operation based on the first result and the second result to generate a test result associated with the scan chain.

In a seventh aspect, in combination with one or more of the first aspect through the sixth aspect, the circuitry includes a control circuit that includes a first input coupled to a first output of the first segment, a second input coupled to at least one other output of at least one other first segment in another scan chain, and an output configured to output test data associated with the first segment and the at least one other first segment.

In an eighth aspect, in combination with one or more of the first aspect through the seventh aspect, the control circuit corresponds to an internal test (INTEST) multiple input signature register (MISR).

In a ninth aspect, in combination with one or more of the first aspect through the eighth aspect, the control circuit corresponds to an external test (EXTEST) multiple input signature register (MISR).

In a tenth aspect, a method includes initiating a test associated with a scan chain of an integrated circuit. The scan chain includes a first segment and a second segment. The method further includes selecting, during the test, as an input to the second segment, one of an output of the first segment or a test pattern that is input to the first segment. The method further includes receiving a test result associated with the scan chain. The test result is based on the selected input to the second segment.

In an eleventh aspect, in combination with the tenth aspect, the test corresponds to a structural test of the integrated circuit, and the selected input to the second segment corresponds to the output of the first segment.

In a twelfth aspect, in combination with one or more of the tenth aspect through the eleventh aspect, the test corresponds to a functional test of the integrated circuit, and the selected input to the second segment corresponds to the test pattern.

In a thirteenth aspect, in combination with one or more of the tenth aspect through the twelfth aspect, the scan chain is associated with a first length in connection with the output of the first segment being the selected input to the second segment, and the scan chain is associated with a second length in connection with the test pattern being the selected input to the second segment. The second length is less than the first length.

In a fourteenth aspect, in combination with one or more of the tenth aspect through the thirteenth aspect, selecting the input to the second segment includes providing a control signal to a multiplexer (MUX) that is coupled to the first segment and to the second segment.

In a fifteenth aspect, in combination with one or more of the tenth aspect through the fourteenth aspect, the method further includes performing an exclusive-OR (XOR) operation to generate the test result based on a first result from the first segment and further based on a second result from the second segment.

In a sixteenth aspect, in combination with one or more of the tenth aspect through the fifteenth aspect, the method further includes providing the output of the first segment to one of a first internal test (INTEST) multiple input signature register (MISR) or to a first external test (EXTEST) MISR and also includes providing a second output of the second segment to one or more of a second INTEST MISR or a second EXTEST MISR.

In a seventeenth aspect, a non-transitory computer-readable medium stores instructions executable by one or more processors to perform one or more operations. The one or more operations include initiating a test associated with a scan chain of an integrated circuit. The scan chain includes a first segment and a second segment. The operations further include selecting, during the test, as an input to the second segment, one of an output of the first segment or a test pattern that is input to the first segment. The operations further include receiving a test result associated with the scan chain. The test result is based on the selected input to the second segment.

In an eighteenth aspect, in combination with the seventeenth aspect, the test corresponds to a structural test of the integrated circuit, and the selected input to the second segment corresponds to the output of the first segment.

In a nineteenth aspect, in combination with one or more of the seventeenth aspect through the eighteenth aspect, the test corresponds to a functional test of the integrated circuit, and wherein the selected input to the second segment corresponds to the test pattern.

In a twentieth aspect, in combination with one or more of the seventeenth aspect through the nineteenth aspect, the scan chain is associated with a first length in connection with the output of the first segment being the selected input to the second segment, and the scan chain is associated with a second length in connection with the test pattern being the selected input to the second segment. The second length is less than the first length.

In the figures, a single block may be described as performing a function or functions. The function or functions performed by that block may be performed in a single component or across multiple components, and/or may be performed using hardware, software, or a combination of hardware and software. To illustrate, various illustrative components, blocks, modules, circuits, and operations may be described in terms of functionality. Whether such functionality is implemented as hardware or software may depend upon the particular application and the overall system design. Skilled artisans may implement the described functionality in varying ways for each particular application, but such implementation decisions should not be interpreted as causing a departure from the scope of the disclosure. Also, the example devices may include components other than those shown, including well-known components such as a processor, memory, and the like.

As used herein, the term “processing core” or “BIST core” may refer to a unit within a processing unit (e.g., a CPU or a GPU) that performs computation and processes instructions where each core may independently execute tasks by reading and executing program instructions. Each processing core may all have access to a memory, such as a cache, which may store data. As used herein, the term “cluster,” “a set of processing cores,” or “a subset of processing cores,” may refer to a group of processing cores that share some resources, such as cache memory or power management features. The clusters may communicate with each other, via a high-speed interconnect or bus, to share data across the entire CPU, which may enable coordinated multitasking. A particular processing core or a set of processing cores may be “functional,” which may be operational and fully capable of executing instructions, handling tasks, and performing computations. A particular processing core or a set of processing cores may be “non-functional,” which may be disabled, faulty, in a standby mode, or otherwise unable to execute certain instructions. In some aspects, a device may fuse or completely turn off non-functional cores or underperforming cores. As used herein, the term “bypass” may refer to skipping BIST when other cores are subject to BIST.

As used herein, the term “built-in self-test (BIST)” may refer to a scheme that enables a component, such as a CPU or a GPU, to test itself automatically without external testing equipment. BIST may generate test patterns or stimuli and then apply these to various parts of the component (e.g., logic gates, memory cells, interconnections) to check for issues, such as non-functional processing cores. In some aspects, a BIST may involve multi-phase tests.

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (such as application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or algorithm disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc, where disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 5, 5, or 50 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus comprising:
a test controller;
a scan chain coupled to the test controller, the scan chain including a first segment and a second segment; and
circuitry coupled to the test controller and the scan chain, the circuitry configured to provide, to the second segment, an output of the first segment in connection with a first test, the circuitry further configured to provide, to the second segment, a test pattern in connection with a second test.

2. The apparatus of claim 1, wherein the first test corresponds to a structural test of an integrated circuit, and wherein the second test corresponds to a functional test of the integrated circuit.

3. The apparatus of claim 1, wherein the first test is associated with a first length of the scan chain, and wherein the second test is associated with a second length of the scan chain, the second length less than the first length.

4. The apparatus of claim 1, wherein the circuitry includes a plurality of multiplexers (MUXes).

5. The apparatus of claim 1, further comprising an exclusive-OR (XOR) gate coupled to an output of the second segment.

6. The apparatus of claim 5, wherein the XOR gate includes:
a first input coupled to a first output of the first segment and configured to receive a first result from the first segment;
a second input coupled to a second output of the second segment and configured to receive a second result from the second segment; and
an output configured to perform an XOR operation based on the first result and the second result to generate a test result associated with the scan chain.

7. The apparatus of claim 1, wherein the circuitry includes a control circuit that includes:
a first input coupled to a first output of the first segment;
a second input coupled to at least one other output of at least one other first segment in another scan chain; and
an output configured to output test data associated with the first segment and the at least one other first segment.

8. The apparatus of claim 7, wherein the control circuit corresponds to an internal test (INTEST) multiple input signature register (MISR).

9. The apparatus of claim 7, wherein the control circuit corresponds to an external test (EXTEST) multiple input signature register (MISR).

10. A method comprising:
initiating a test associated with a scan chain of an integrated circuit, the scan chain including a first segment and a second segment;
during the test, selecting, as an input to the second segment, one of an output of the first segment or a test pattern that is input to the first segment; and
receiving a test result associated with the scan chain, the test result based on the selected input to the second segment.

11. The method of claim 10, wherein the test corresponds to a structural test of the integrated circuit, and wherein the selected input to the second segment corresponds to the output of the first segment.

12. The method of claim 10, wherein the test corresponds to a functional test of the integrated circuit, and wherein the selected input to the second segment corresponds to the test pattern.

13. The method of claim 10, wherein the scan chain is associated with a first length in connection with the output of the first segment being the selected input to the second segment, and wherein the scan chain is associated with a second length in connection with the test pattern being the selected input to the second segment, the second length less than the first length.

14. The method of claim 10, wherein selecting the input to the second segment includes providing a control signal to a multiplexer (MUX) that is coupled to the first segment and to the second segment.

15. The method of claim 10, further comprising performing an exclusive-OR (XOR) operation to generate the test result based on a first result from the first segment and further based on a second result from the second segment.

16. The method of claim 10, further comprising:
providing the output of the first segment to one of a first internal test (INTEST) multiple input signature register (MISR) or to a first external test (EXTEST) MISR; and
providing a second output of the second segment to one or more of a second INTEST MISR or a second EXTEST MISR.

17. A non-transitory computer-readable medium storing instructions executable by one or more processors to perform one or more operations, the one or more operations comprising:
initiating a test associated with a scan chain of an integrated circuit, the scan chain including a first segment and a second segment;
during the test, selecting, as an input to the second segment, one of an output of the first segment or a test pattern that is input to the first segment; and
receiving a test result associated with the scan chain, the test result based on the selected input to the second segment.

18. The non-transitory computer-readable medium of claim 17, wherein the test corresponds to a structural test of the integrated circuit, and wherein the selected input to the second segment corresponds to the output of the first segment.

19. The non-transitory computer-readable medium of claim 17, wherein the test corresponds to a functional test of the integrated circuit, and wherein the selected input to the second segment corresponds to the test pattern.

20. The non-transitory computer-readable medium of claim 17, wherein the scan chain is associated with a first length in connection with the output of the first segment being the selected input to the second segment, and wherein the scan chain is associated with a second length in connection with the test pattern being the selected input to the second segment, the second length less than the first length.
